(19) United States
(12) Patent Application Publication
(10) Pub. No.: US 2015/0155416 A1
(43) Pub. Date: Jun. 4, 2015

(54) SOLAR CELL MODULE

(71) Applicant: SANYO Electric Co., Ltd., Osaka (JP)

(72) Inventor: Kengo MATSUNE, Hyogo (JP)

(21) Appl. No.: 14/621,983

(22) Filed: Feb. 13, 2015

Related U.S. Application Data
(63) Continuation of application No. PCT/JP2012/073805, filed on Sep. 18, 2012.

(51) Int. Cl. H01L 31/054; H01L 31/048; H02S 40/22; H01L 31/02

(52) U.S. Cl. CPC H01L 31/0547; H01L 31/02013; H01L 31/048; H02S 40/22

(57) ABSTRACT

Disclosed is a solar cell module that comprises a first protective member, a second protective member opposed to the first protective member and being more flexible than the first protective member, a solar cell comprising a first main surface facing toward the first protective member and a second main surface facing toward the second protective member, and an interconnection wiring member bonded to the second main surface of the solar cell. A recessed portion and a protruding portion are provided on each of a pair of main surfaces of the interconnection wiring member such that the protruding portion of one of the main surfaces and the recessed portion of the other main surface are located to correspond to each other. And two widthwise-opposite end portions of the interconnection wiring member extend toward the first protective member in a thickness direction of the solar cell.

### CROSS REFERENCE TO RELATED APPLICATIONS

This application is a continuation application of International Application No. PCT/JP2012/073805, filed on Sep. 18, 2012, entitled “SOLAR CELL MODULE”, the entire contents of which are incorporated herein by reference.

### TECHNICAL FIELD

The invention relates to a solar cell module.

### BACKGROUND

In recent years, solar cell modules have attracted rising attention as low-environmental-load energy sources. For example, Japanese Patent Application Publication No. 2006-13406 describes a solar cell module including cells electrically connected to each other with interconnection wiring members. In that described solar cell module, one end portion of each interconnection wiring member is bonded to a light-receiving surface of one of two adjacent solar cells, and the other end portion of the interconnection wiring member is bonded to aback surface of other of the two adjacent solar cells. A main surface of the interconnection wiring member on the light-receiving surface side is provided with recessed portions and protruding portions. These portions improve the use efficiency of light impinging on the interconnection wiring member. Meanwhile, a main surface of the interconnection wiring member on the back-surface side is provided as a flat surface.

### SUMMARY OF THE INVENTION

A solar cell module according to an embodiment includes a first protective member, a second protective member, a solar cell, and an interconnection wiring member. The second protective member is opposed to the first protective member. The second protective member has higher flexibility than the first protective member. The solar cell has a first main surface and a second main surface. The first main surface faces toward the first protective member. The second main surface faces toward the second protective member. The interconnection wiring member is bonded to the second main surface of the solar cell. A recessed portion and a protruding portion are provided on each of a pair of main surfaces of the interconnection wiring member such that the protruding portion of one of the main surfaces and the recessed portion of other of the main surfaces are positioned to correspond to each other. Two widthwise-opposite end portions of the interconnection wiring member extend toward the first protective member in a thickness direction of the solar cell.

### BRIEF DESCRIPTION OF THE DRAWINGS

FIG. 1 is a schematic cross-sectional view of a solar cell module in a first example.

FIG. 2 is a schematic cross-sectional view of a solar cell in the first example.

FIG. 3 is a schematic cross-sectional view of a solar cell in a second example.

FIG. 4 is a schematic cross-sectional view of a solar cell in a third example.

### DETAILED DESCRIPTION

Embodiments provide enhanced light collection efficiency and enhanced stability by virtue of interconnect members having recessed and protruding portions that bind (preferably via resin) with alternative solar cell surfaces. In an embodiment, contours of the interconnect encourage light refraction for enhanced absorption. In an embodiment, the contoured connections provide greater stability, particularly when provided on both sides of a solar cell surface.

Hereinafter, examples of preferred embodiments of the invention are described. It should be noted, however, that the following embodiments are merely illustrative examples. The claimed invention is not limited by any of the following embodiments.

Moreover, components having substantially the same functions are denoted by the same reference numerals in drawings referenced in the examples and the like. Further, the drawings referenced in the examples and the like are schematically drawn, and dimensional proportions and the like of objects drawn in the drawings may be different from those of actual objects. Dimensional proportions and the like of objects may be different between the drawings. Specific dimensional proportions of objects should be determined with reference to the following description.

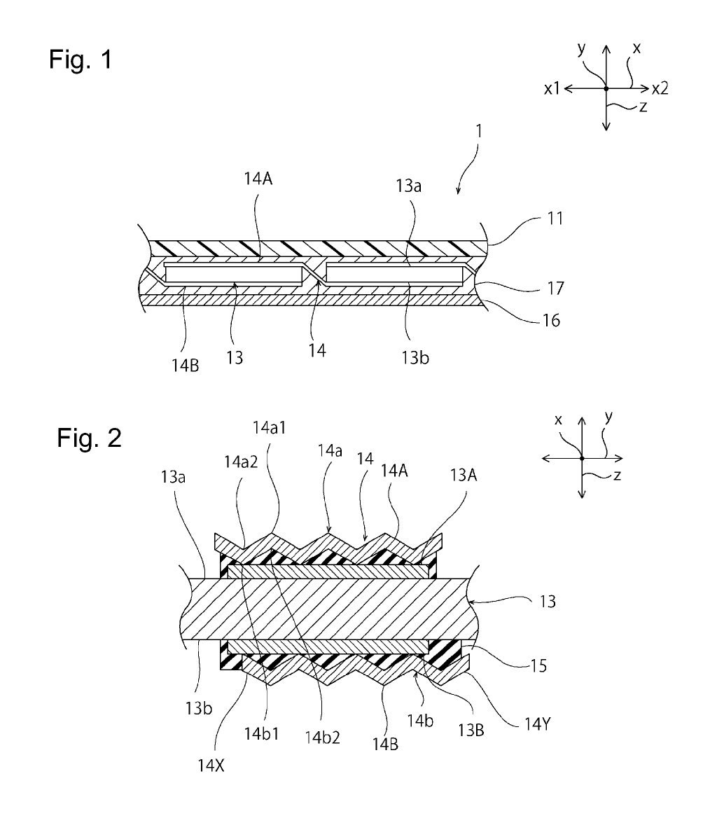

As illustrated in FIG. 1, solar cell module 1 includes solar cells 13. A solar cell (shown as “13” in the drawing) includes first main surface 13a and second main surface 13b. First main surface 13a constitutes a light-receiving surface, and second main surface 13b constitutes a back surface. It should be noted that a light-receiving surface means one main surface, of a pair of main surfaces of a solar cell, by which light is principally received, and the other main surface constitutes a back surface. Solar cell (shown as “13” in the drawing) includes first electrode 13A (see FIG. 2) on the first main surface 13a side and second electrode 13B on the second main surface 13b side.

Solar cells 13 are electrically connected with interconnection wiring members 14. Specifically, first electrode 13A of one solar cell (shown as “13” in the drawing) of two adjacent solar cells, which is located on the first main surface 13a side, and second electrode 13B of the other solar cell, which is located on the second main surface 13b side, are electrically connected with interconnection wiring member 14.

As illustrated in FIG. 2, interconnection wiring member 14 and a solar cell (shown as “13” in the drawing) are bonded with resin adhesive layer 15 including cured resin adhesive. Resin adhesive layer 15 maybe made of cured resin adhesive alone. In that case, interconnection wiring member 14 and solar cell 13 are preferably bonded to each other with interconnection wiring member 14 and first or second electrode 13A or 13B being in contact with each other. Moreover, resin adhesive layer 15 may include cured resin adhesive containing conductive material dispersed therein.

Over first main surfaces 13a of solar cells 13, first protective member 11 is arranged. First protective member 11 is preferably translucent or transparent, and can be formed of, for example, a glass plate. Meanwhile, over second main surfaces 13b of solar cells 13, second protective member 16 is arranged. Second protective member 16 can be formed of, for example, a resin sheet. That is, solar cells 13 are arranged between first protective member 11 and second protective member 16. Second protective member 16 may be formed of a resin sheet alone, or may be formed of a resin sheet including a barrier layer such as a metal layer or an inorganic oxide layer. In the case where light impinging on the back surface is used to generate electric power, second protective member 16 is preferably translucent or transparent.

Sealing member 17 is arranged between first protective member 11 and second protective member 16. Solar cells 13 and interconnection wiring members 14 are encapsulated in this sealing member 17. Sealing member 17 can be made of, for example, crosslinkable resin such as ethylene-vinyl acetate copolymer (EVA) or noncrosslinkable resin such as polyolefin. Sealing member 17 provided between first protective member 11 and solar cells 13 is preferably translucent or transparent. In the case where light impinging on the back surface is used to generate electric power, sealing member 17 provided between second protective member 16 and solar cells 13 is preferably translucent or transparent.

A transverse cross-section of interconnection wiring member 14 has a zigzag shape along a widthwise direction of interconnection wiring member 14.

Interconnection wiring member 14 has first main surface 14a and second main surface 14b. First main surface 14a faces toward the light-receiving surface (first protective member 11), and second main surface 14b faces toward the back surface (second protective member 16). Each of first and second main surfaces 14a and 14b is provided with recessed portions and protruding portions. The recessed portions and the protruding portions extend in an x-axis direction, which is an extending direction of interconnection wiring member 14. Specifically, recessed portions and protruding portions of first main surface 14a are formed such that protruding portions 14a1 extending in the x-axis direction and recessed portions 14a2 extending in the x-axis direction are alternately arranged in a y-axis direction perpendicular to the x-axis direction. Recessed portions and protruding portions of second main surface 14b are formed such that protruding portions 14b1 extending in the x-axis direction and recessed portions 14b2 extending in the x-axis direction are alternately arranged in the y-axis direction perpendicular to the x-axis direction.

The recessed portions and the protruding portions of first main surface 14a and the recessed portions and the protruding portions of second main surface 14b are provided such that protruding portions 14a1 of first main surface 14a and recessed portions 14b2 of second main surface 14b are located to correspond to each other. In the embodiment illustrated in

FIG. 2, the positions of protruding portions 14a1 of first main surface 14a match the positions of recessed portions 14b2 of second main surface 14b in the y-axis direction. Accordingly, protruding portions 14a1 of first main surface 14a and recessed portions 14b2 of second main surface 14b are opposed to each other in a z-axis direction, which is the thickness direction of solar cell 13. The recessed portions and the protruding portions of first main surface 14a and the recessed portions and the protruding portions of second main surface 14b are provided such that recessed portions 14a2 of first main surface 14a and protruding portions 14b1 of second main surface 14b are placed to correspond to each other. In the embodiment illustrated in FIG. 2, the positions of recessed portions 14a2 of first main surface 14a match the positions of protruding portions 14b1 of second main surface 14b with respect to the y-axis direction. Accordingly, recessed portions 14a2 of first main surface 14a and protruding portions 14b1 of second main surface 14b are opposed to each other in the z-axis direction.

Light-receiving-surface-side portion 14A of interconnection wiring member 14, which is located on the light-receiving surface side of solar cell 13, and back-surface-side portion 14B of interconnection wiring member 14, which is located on the back-surface side of solar cell 13, are opposed to each other across solar cell 13 in the z-axis direction. Protruding portions 14b1 provided on second main surface 14b of light-receiving-surface-side portion 14A, which is the main surface on the solar cell 13 side, and protruding portions 14a1 provided on first main surface 14a of back-surface-side portion 14B, which is the main surface on the solar cell 13 side, are opposed to each other across solar cell 13 in the z-axis direction.

The above-described interconnection wiring member 14 can be fabricated by pressing a metal plate in which two main surfaces are flat surfaces.

In solar cell module 1, recessed portions and protruding portions are provided on first main surface 14a of interconnection wiring member 14, which faces toward the light-receiving surface. This can improve the use efficiency of light impinging on the first main surface 14a. Accordingly, improved photoelectric conversion efficiency can be obtained. Specifically, at least part of light reflected by interconnection wiring member 14 is reflected at an interface between first protective member 11 on the light-receiving surface side and sealing member 17 or an interface between first protective member 11 and air to impinge on first main surface 13a of solar cell 13. Thus, the use efficiency of light impinging on interconnection wiring member 14 can be improved.

In terms of the improvement of photoelectric conversion efficiency, recessed portions and protruding portions need to be provided only on the main surface of the interconnection wiring member on the light-receiving surface side, and recessed portions and protruding portions do not need to be provided on the main surface thereof on the back-surface side. However, in that case, the interconnection wiring member has high rigidity, and a fracture or a crack may occur in the solar cells when stress occurs between the interconnection wiring member and the solar cell during, for example, use or fabrication.

Meanwhile, in solar cell module 1, recessed portions and protruding portions are provided on each of first and second main surfaces 14a and 14b of interconnection wiring member 14 such that protruding portions 14a1 of first main surface 14a and recessed portions 14b2 of second main surface 14b are located to correspond to each other. Accordingly, interconnection wiring member 14 easily elastically deforms in the thickness direction (z-axis direction) of interconnection wiring member 14. Moreover, in the case where interconnection wiring member 14 is fabricated by press forming, pressing pressure can be lower than in the case where an interconnection wiring member provided with recessed portions and protruding portions on only one surface is fabricated by press forming. Accordingly, work-hardening can be lessened, and therefore it is easy to lower the rigidity of interconnection wiring member 14. Thus, high stress is less likely to occur between solar cell 13 and interconnection wiring member 14. Accordingly, the frequency of a fracture or a crack occurring in the solar cells during use or fabrication can be reduced. Therefore, improved reliability and high manufacturing efficiency can be realized.

The configuration of solar cell module 1, which can reduce stress occurring between solar cell 13 and interconnection wiring member 1, is effective particularly in the case where interconnection wiring member 14 is bonded to solar cell 13 with resin adhesive layer 15, because interconnection wiring member 14 and solar cell 13 need to be bonded to each other with resin adhesive by the application of pressure.

Moreover, in solar cell module 1, protruding portions 14b1 provided on second main surface 14b of light-receiving-surface-side portion 14A, which is the main surface on the solar cell 13 side, and protruding portions 14a1 provided on first main surface 14a of back-surface-side portion 14B, which is the main surface on the solar cell 13 side, are opposed to each other across solar cell 13 in the z-axis direction. This effectively reduces the frequency of a fracture or a crack occurring in solar cells 13 when compressive stress occurs between light-receiving-surface-side portion 14A and back-surface-side portion 14B.

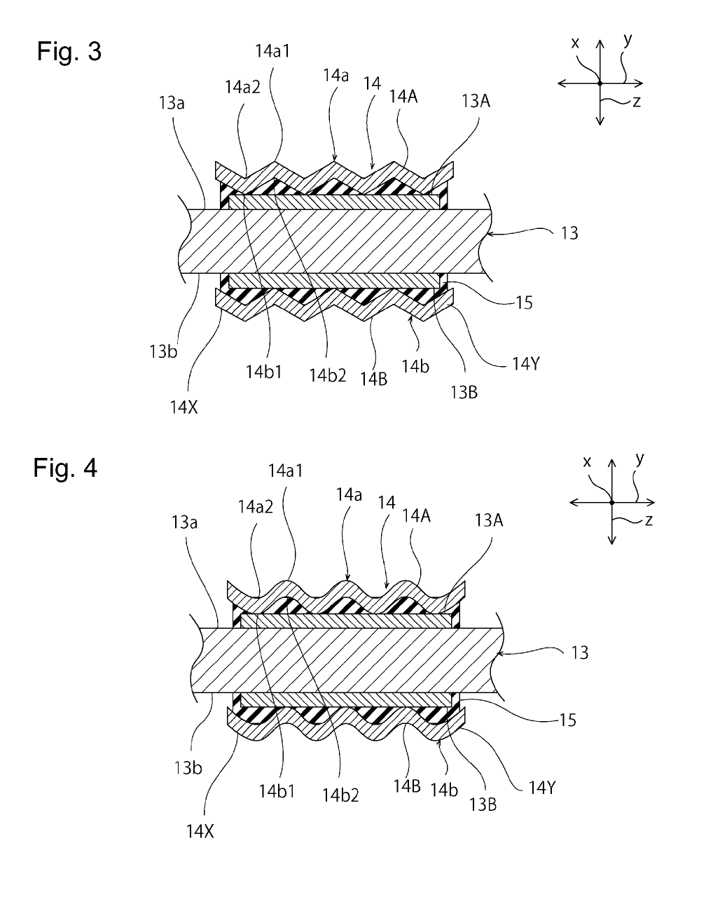

However, protruding portions 14b1 provided on second main surface 14b of light-receiving-surface-side portion 14A, which is the main surface on the solar cell 13 side, and protruding portions 14a1 provided on first main surface 14a of back-surface-side portion 14B, which is the main surface on the solar cell 13 side, do not necessarily need to be opposed to each other across solar cell 13 in the z-axis direction. For example, as illustrated in FIG. 3, protruding portions 14b1 provided on second main surface 14b of light-receiving-surface-side portion 14A, which is the main surface on the solar cell 13 side, and recessed portions 14a2 provided on first main surface 14a of back-surface-side portion 14B, which is the main surface on the solar cell 13 side, may be opposed to each other across solar cell 13 in the z-axis direction.

In this embodiment, an explanation has been made of an example in which protruding portions 14a1 and 14b1 have triangular transverse cross-sections and in which recessed portions and protruding portions are formed by alternately disposing two kinds of planes extending in respective directions crossing each other. However, the invention is not limited to this configuration. For example, as illustrated in FIG. 4, recessed portions and protruding portions maybe formed by a curved surface. Protruding portions 14a1 and 14b1 may have rounded transverse cross-sections.

Moreover, in this embodiment, an explanation has been made of an example of a solar cell module which generates electric power using light impinging on one main surface, of the pair of main surfaces of a solar cell, by which light is principally received. However, the invention is not limited to this configuration. For example, the invention can also be applied to a solar cell module in which each of first protective member 11 and second protective member 16 is translucent or transparent and which generates electric power using light impinging on the back surface as well as light impinging on the light-receiving surface. In that case, similar to light reflected by the interconnection wiring member on the light-receiving surface, light reflected by the interconnection wiring member on the back surface is reflected at an interface between the second protective member on the back-surface side and the sealing member or an interface between the second protective member and air to impinge on the second main surface of the solar cell. Thus, the use efficiency of light impinging on the interconnection wiring members can be improved.

In the case where recessed portions and protruding portions are provided on both of first and second main surfaces of interconnection wiring member 14 as in this embodiment, two widthwise-opposite end portions of the interconnection wiring member may have sharp corner portions on the second-protective-member side. Accordingly, the interconnection wiring member may damage or break through the second protective member. This potentially occurs in the case where the second protective member is more flexible than the first protective member, such as the case where a glass plate and a resin sheet are employed as the first protective member and the second protective member, respectively.

In solar cell module 1, two widthwise-opposite end portions 14X and 14Y of interconnection wiring member 14 extend toward first protective member 11 in the z-axis direction, which is the thickness direction of solar cell 13. Accordingly, two end portions 14X and 14Y are less prone to damage or break through second protective member 16. Thus, more improved reliability can be realized.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A solar cell module comprising:
a first protective member;
a second protective member opposed to the first protective member and being more flexible than the first protective member;
a solar cell comprising a first main surface facing toward the first protective member and a second main surface facing toward the second protective member; and
an interconnection wiring member bonded to the second main surface of the solar cell,
wherein a recessed portion and a protruding portion are provided on each of a pair of main surfaces of the interconnection wiring member such that the protruding portion of one of the main surfaces and the recessed portion of the other main surface are located to correspond to each other, and
two widthwise-opposite end portions of the interconnection wiring member extend toward the first protective member in a thickness direction of the solar cell.

2. The solar cell module according to claim 1, further comprising a resin adhesive layer bonding the interconnection wiring member and the solar cell.

3. The solar cell module according to claim 1, wherein the recessed portion and the protruding portion extend in an extending direction of the interconnection wiring member.

4. The solar cell module according to claim 1, wherein
each of the first protective member and the sealing member is translucent or transparent, and
at least part of light reflected by the interconnection wiring member is reflected at any one of an interface between the first protective member and the sealing member and an interface between the first protective member and air, and impinges on the first main surface of the solar cell.

5. The solar cell module according to claim 4, wherein
the second protective member is translucent or transparent, and
at least part of light reflected by the interconnection wiring member is reflected at any one of an interface between the second protective member and the sealing member and an interface between the second protective member and air, and impinges on the second main surface of the solar cell.
